(19) United States
(12) Patent Application Publication
(10) Pub. No.: US 2023/0200245 A1
(43) Pub. Date: Jun. 22, 2023

(54) HYBRID CHEMICAL AND PHYSICAL VAPOR DEPOSITION OF TRANSITION-METAL-ALLOYED PIEZOELECTRIC SEMICONDUCTOR FILMS

(71) Applicant: UNIVERSITY OF HOUSTON SYSTEM, Houston, TX (US)

(72) Inventors: Jae-Hyun Ryou, Katy, TX (US); Mina Moradnia, Pearland, TX (US); Arul Chakkaravarthi Arjunan, Newberry, FL (US); Gary S. Tompa, Belle Mead, NJ (US)

(21) Appl. No.: 18/083,236

(22) Filed: Dec. 16, 2022

Related U.S. Application Data
(60) Provisional application No. 63/291,135, filed on Dec. 17, 2021.

(51) Int. Cl. H10N 30/093; H10N 30/85; C23C 16/30; C23C 16/455; C23C 14/06

(52) U.S. Cl. CPC H10N 30/093; H10N 30/85; C23C 16/303; C23C 16/45561; C23C 16/45514; C23C 14/0617

(57) ABSTRACT

A chamber of a hybrid chemical and physical vapor deposition (HybCPVD) provides high-quality and uniform films on relatively large multiple wafers per growth run at reasonably high deposition rates using a scalable high-throughput process. Transition-metal-alloyed III-N single-crystalline and textured thin films are epitaxially and non-epitaxially deposited on a suitable substrate (of, for example, silicon or a metal such as aluminum or titanium) by providing a mixture of various gases in a deposition/growth chamber. The precursors for the chemical reactions include vapor phase of elements of transition metals, vapor phase of chlorides, and vapor phase of hydride. This growth technique provides high growth rate and high-quality epitaxial materials.

### PRIORITY

This application claims the benefit of U.S. Provisional 63/291,135, filed Dec. 17, 2021, which is hereby incorporated by reference as if submitted in its entirety.

### BACKGROUND OF THE INVENTION

Previously developed deposition techniques include sputtering deposition, molecular beam epitaxy (MBE), hydride vapor phase epitaxy (HVPE), and metal organic chemical vapor deposition (MOCVD). These techniques possess the drawbacks of compromised thickness uniformity, throughput, and material quality of the thin films. For extended and emerging applications of the thin films for wireless communication, energy harvesting, sensing, and ferroelectric semiconductors, the aforementioned limitations need to be overcome.

### SUMMARY

To overcome the limitations of the previous growth methods of transition-metal-alloyed III-nitride thin films, a hybrid chemical vapor deposition (HybCVD) or hybrid vapor phase epitaxy (HybVPE) method for epitaxial growth and deposition of transition-metal-alloyed group-III-nitride thin films is provided. As described below, this technique may be used to achieve transition-metal-alloyed III-N wide-bandgap piezoelectric semiconductor thin films consisting of group IIIb (or group 3) transition-metal-nitride, such as scandium nitride (ScN) and yttrium nitride (YN), and group IIIa-nitride (or group 13, boron group), such as boron nitride (BN), aluminum nitride (AlN), gallium nitride (GaN), and indium nitride (InN). The technique described herein may employ various forms of precursors, such as vapor phase of pure transition metal, vapor phase chloride form of group III element, and ammonia. The alloys may include various combinations of group IIIb-nitrides and group IIIa-nitrides, such as ScₓAl₁₋ₓN, ScₓB₁₋ₓN, ScₓGa₁₋ₓN, ScₓIn₁₋ₓN, YxAl1-xN, YxB1-xN, YxGa1-xN, YₓIn₁₋ₓN, combinations thereof, etc.

The HybCVD (or HybVPE) growth method addresses the limitations of thickness uniformity and quality of materials grown by sputtering growth technique, which is currently the prominent method for epitaxial growth of AlScN. Additionally, the disclosed process overcomes the limitations of other existing techniques, such as low molar flow rate of precursors in MOCVD, limited chemistry for the formation of transition-metal-nitride in HVPE, or very low growth rate and necessity of extremely low-pressure growth limit in MBE. Accordingly, the disclosed method results in a piezoelectric semiconductor film having improved crystalline quality, better stoichiometry of anions and cations, easier scale-up and high throughput of the manufacturing process, and/or improved thickness uniformity.

### BRIEF DESCRIPTION OF THE DRAWINGS

FIG. 1 shows the Gibbs free energy for each chemical reaction.

FIG. 2 shows a chamber in accordance with an embodiment of the disclosure.

FIG. 3 shows a representative plot graph in accordance with an embodiment of the disclosure.

FIG. 4A shows representative results in accordance with an embodiment of the disclosure.

FIG. 4B shows additional representative results in accordance with an embodiment of the disclosure.

FIG. 5A shows an example of a thin film in accordance with an embodiment of the disclosure.

FIG. 5B shows another example of a thin film in accordance with another embodiment of the disclosure.

FIG. 5C shows an example of a thin film in accordance with an embodiment of the disclosure.

FIG. 5D shows another example of a thin film in accordance with another embodiment of the disclosure.

### DETAILED DESCRIPTION

In the following description, for purposes of explanation, numerous specific details are set forth to provide a thorough understanding of the disclosed concepts. As part of this description, some of this disclosure's drawings represent structures and devices in block diagram form to avoid obscuring the novel aspects of the disclosed embodiments. In this context, references to numbered drawing elements without associated identifiers (e.g., 100) refer to all instances of the drawing element with similar alphanumeric identifiers (e.g., 100a and 100b). Further, as part of this description, some of this disclosure's drawings may be provided in the form of a flow diagram. The boxes in any flow chart may be presented in a particular order. However, the particular flow of any flow diagram is used only to exemplify one embodiment. In other embodiments, any of the various components depicted in the flow chart may be deleted, or the components may be performed in a different order, or even concurrently. In addition, other embodiments may include additional steps not depicted as part of the flow chart. The language used in this disclosure has been principally selected for readability and instructional purposes and may not have been selected to delineate or circumscribe the disclosed subject matter. Reference in this disclosure to “one embodiment” or to “an embodiment” means that a particular feature, structure, or characteristic described in connection with the embodiment is included in at least one embodiment, and multiple references to “one embodiment” or to “an embodiment” should not be understood as necessarily all referring to the same embodiment or to different embodiments.

A hybrid chemical vapor deposition (HybCVD) and hybrid vapor phase epitaxy (HybVPE) method for epitaxial growth and deposition of transition-metal-alloyed group-III-nitride thin films is disclosed. As described below, this technique may be used to achieve transition-metal-alloyed III-N wide-bandgap piezoelectric semiconductor thin films consisting of group IIIb (or group 3) transition-metal-nitride, such as scandium nitride (ScN) and yttrium nitride (YN), and group IIIa-nitride (or group 13, boron group), such as boron nitride (BN), aluminum nitride (AlN), gallium nitride (GaN), and indium nitride (InN). The technique described herein may employ various forms of precursors, such as vapor phase of pure transition metal, vapor phase chloride form of group III element, and ammonia. The alloys may include various combinations of group IIIb-nitrides and group IIIa-nitrides, such as ScₓAl₁₋ₓN, ScₓB₁₋ₓN, ScₓGa₁₋ₓN, ScₓIn₁₋ₓN, YxAl1-xN, YxB1-xN, YxGa1-xN, YₓIn₁₋ₓN, combinations thereof, etc.

To overcome the limitations of the previous growth methods of transition-metal-alloyed III-nitride thin films, the hybrid deposition and growth technique described herein may combine advantages of different precursors, such as vapor phase of a pure transition metal, vapor phase chloride form of a group III element, or ammonia. The HybCVD growth method may be employed to address the limitations of thickness uniformity and quality of materials grown by sputtering growth technique, which is currently the prominent method for epitaxial growth of AlScN. Additionally, the disclosed process overcomes the limitations of existing techniques, such as low molar flow rate of precursors in MOCVD, limited chemistry for the formation of transition-metal-nitride in HVPE, or very low growth rate and necessity of extremely low-pressure growth limit in MBE. Some advantages of the fabrication techniques (described more fully below) over prior techniques (such as sputtering) result in a piezoelectric semiconductor film having improved crystalline quality and better stoichiometry of anions and cations, easier scale-up and high throughput of the manufacturing process, and/or improved thickness uniformity.

Before explaining at least one embodiment in detail, the concepts set forth herein are not limited in their application to the construction details or component arrangements set forth in the following description or illustrated in the drawings. It should also be understood that the phraseology and terminology employed herein are merely for descriptive purposes and should not be considered limiting.

It should further be understood that any one of the described features may be used separately or in combination with other features. Other embodiments of devices, systems, methods, features, and advantages described herein will be or become apparent to one with skill in the art upon examining the drawings and the detailed description herein. It's intended that all such additional devices, systems, methods, features, and advantages be protected by the accompanying claims.

### I. Extended Applications of Piezoelectric Thin Films and Effect of Transition Metal on Structure and Piezoelectric Properties of III-N Films

Group IIIa-nitride (here in “III-N”) thin-film compounds consisting of Group IIIa (or group 13, boron group) (herein “Group III”) and nitrogen (N), including BN, AlN, GaN, InN, and their alloys of BₓAl_{y}Ga_{z}In_{1-x-y-z}N (0≤x≤1, 0≤y≤1, 0≤z≤1) have been considered as a promising candidate for various electro-acoustic, mechanical energy harvesting, and sensing applications due to their piezoelectric properties, as well as already developed high-temperature high-power electronic and visible and short-wavelength optoelectronic applications. However, the relatively low piezoelectric response of III-N materials as compared to a typical piezoelectric material such as lead zirconate titanate (Pb[ZrₓTi₁₋ₓ]O₃, PZT) has posed limitations in their performance as a highly functional piezoelectric material. Therefore, the piezoelectric performance of III-N films needs to be further improved for extended applications. Alloying with (or doping with) a group IIIb (or group 3) transition metal (herein “transition metal”), such as scandium (Sc), yttrium (Y), etc., with the III-N films offers an effective route to enhance the piezoelectric coefficients of III-N films. For example, Sc incorporation as an alloy element to substitute for aluminum (Al) in wurtzite-structure AlN, forming ScₓAl₁₋ₓN, significantly enhances the piezoelectric coefficients of AlN-based materials.

The enhanced piezoelectric coefficients of III-N films by transition-metal alloying are expected to bring beneficial impacts in the following applications:
(1) Wireless communication: ScAlN thin films and other transition-metal-alloyed III-N thin films will bring direct improvements in electro-acoustic devices, e.g., bulk acoustic wave (BAW) and surface acoustic wave (SAW) devices. Electromechanical coupling factor (kₜ²) as a determining factor for bandwidth in filters is relatively low in AlN. Sc-alloyed AlN could improve kₜ² up to 4 times by retaining low dielectric losses and increasing the piezoelectric coefficients (such as d₃₃) combined with a decrease in the stiffness constant along the c-axis (C₃₃). BAW and SAW devices have been used as a filter at frequencies operating below 2.6 GHz band; however, high-performance filters for next generation wireless communication are required to operate at 3-10 GHz frequency range to provide low loss, small form factor, and wide bandwidth. Reducing the thickness of piezoelectric materials to submicron ranges is a practical way to scale up the frequency of the filters. However, reducing the film thickness makes it hard to maintain high electromechanical coupling. Single-crystalline ScAlN was reported to show high electromechanical coupling with submicron film thickness.
(2) Sensors: Control of the intrinsic film stress was exhibited over a wide range from strongly tensile to strongly compressive for all the investigated Sc contents. The improved piezoelectric coefficients together with the possibility of stress control allowed the fabrication of suspended MEMS structures with electromechanical coupling coefficient enhanced in comparison with AlN. Higher piezoelectric activity of ScAlN thin film can improve sensitivity of MEMS magnetoelectric (ME) sensors by reducing the requirements of electronic systems, which allows higher sensitivity at low frequencies of wideband operation of ME sensors. Also, piezoelectric materials are used as a transducer to measure force, strain, acceleration, and vibration utilizing their direct piezoelectric effect. In addition, piezoelectric sensors can be used as an immunosensor using their resonating properties under an external alternating electrical field. The higher electromechanical coupling factor of transition-metal-alloyed III-N thin films will result in improved sensitivity for the operation of the sensors.
(3) Mechanical energy harvesting: Biomechanical energy is the most promising energy source for wearable systems since it is widely available for every living human being and is less limited by time and location than other energy sources like light and heat. Therefore, piezoelectric power generators have been developed to scavenge the biomechanical energy of the human body and organs. Sc incorporation in wurtzite-structure AlN increases the electromechanical coupling factor, increasing the efficiency of the energy harvesting.
(4) Ferroelectrics: The substitution of the Al atoms with the larger Sc atoms causes an increase in the average bond lengths and a decrease in the average bonding angle, resulting in a flattening of the tetrahedral arrangement in the underlying wurtzite crystal structure. In addition, increasing Sc content results in the continuous distortion of the original wurtzite-type crystal structure towards a layered-hexagonal structure. Tensile strain of the structure demonstrates the appearance of ferroelectricity in ScₓAl₁₋ₓN. Therefore, an Sc-enhanced transition-metal-alloyed III-N thin film is capable of functioning not only as a piezoelectric material but also as a ferroelectric material. Importantly, the ferroelectric switching feature of the material can pave the way to meet the urgent demand of high-performance thin film ferroelectrics in semiconductor technology based on controlled electrical polarization¹. ¹S. Fichtner, N. Wolff, F. Lofink, L. Kienle, and B. Wagner, “AlScN: A III-V semiconductor based ferroelectric,” J. Appl. Phys., vol. 125, no. 11, 2019, doi: 10.1063/1.5084945. N. Wolff et al., “Atomic scale confirmation of ferroelectric polarization inversion in wurtzite-type AlScN,” J. Appl. Phys., vol. 129, no. 3, p. 034103, 2021, doi: 10.1063/5.0033205.

In summary, transition-metal-alloyed III-N thin films become increasingly important in extended applications of wireless communication, energy harvesting, sensing, and ferroelectric semiconductors. Existing thin-film deposition techniques cannot meet the requirements of high material quality and high-throughput manufacturability for the transition-metal-alloyed III-N thin films. Here, the inventors disclose a process concept, resulting structure, and apparatus of a new thin-film deposition technique to overcome the limitations of existing deposition techniques and structures.

Importantly, advantages of the described process concept and resulting structure allow for any of the embodiments described in this disclosure to achieve a piezoelectric semiconductor film including at least one characteristic selected from the group consisting of:
1. a piezoelectric coefficient d₃₃ in the range of greater than 5 pC/N (with a preferred range of greater than 25 pC/N), whereas current films have a piezoelectric coefficient d₃₃ in the range of 5 pC/N-25 pC/N;
2. an electromechanical coupling factor kₜ² in the range of greater than 10% (with a preferred range of 15%-25%), whereas current films have an electromechanical coupling factor kₜ² in the range of 5%-10%;
3. a crystalline quality in terms of full-width-at-half-maximum from (0002) X-ray diffraction rocking curves in the range of less than 2° (with a preferred range of 0.01°-1.99°), whereas current films have a corresponding crystalline quality in the range of 2°-10°.

To accomplish a piezoelectric semiconductor film having the above characteristics, the film may have a thickness uniformity of less than 10%. In some embodiments, the film may have a thickness uniformity of less than 10% with respect to the underlying substrate having a diameter of 2 inches or greater. Thickness uniformity is generally characterized by % of thickness non-uniformity defined by “(max thickness−min thickness) divided by average thickness.” In the semiconductor and coating industry, some edge areas are excluded from the measurement in what is known as “edge exclusion,” e.g., 2-mm edge exclusion.

Additionally, for any of the embodiments described in this disclosure, the piezoelectric semiconductor film is capable of being formed in a thickness in the range of 5 nm-500 μm, a film strain controllability in the range of 0%-5%, and a band-gap energy in the range of 0.7 eV-6.2 eV.

### II. Literature Survey and Prior Arts: Current Status of Epitaxial Growth of Transition-Metal-Alloyed III-N Piezoelectric Thin Films

Transition-metal-alloyed III-N compounds may be deposited by different existing growth methods, such as metalorganic chemical vapor deposition (MOCVD), molecular beam epitaxy (MBE), hydride vapor phase epitaxy (HVPE), and sputtering deposition techniques. Among them, MBE, MOCVD, and sputtering systems have been reported for the growth of AlN alloyed with Sc as one of the transition metal elements.

Current methods of epitaxial growth of the alloyed III-N use HVPE, MBE, MOCVD, and sputtering deposition techniques. Among them, sputtering deposition, MBE, and MOCVD were reported for ScAlN, ScGaN, and YGaN thin film growth, while HVPE method was for the growth of AlN alloyed by gallium (Ga), i.e., AlGaN without transition metal alloying.

For the HVPE growth method, chlorides are used as precursors for both Al and Ga elements and ammonia (NH₃) as a precursor for N element. One method was found for the deposition of AlGaN. However, this technique cannot be extended to III-N with transition metal alloys due the problems related to the chloride form of Sc. The following chemical reactions can be considered to produce Sc-chloride precursor for HVPE.

2Sc(s,l)+2HCl(g)→2ScCl+H₂(g) (chemical formula 1)

2Sc(s,l)+4HCl(g)→2ScCl₂(g)+2H₂(g) (chemical formula 2)

2Sc(s,l)+6HCl(g)→2ScCl₃(g)+3H₂(g) (chemical formula 3)

ScCl₃(g)+ScCl₃(g)Sc₂Cl₆(g) (chemical formula 4)

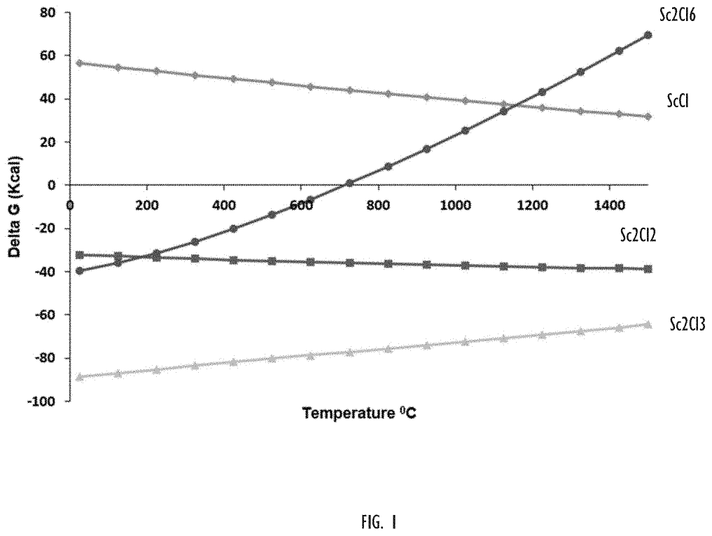

FIG. 1 shows the Gibbs free energy for each chemical reaction. ScCl (chemical formula 1) are not expected to be produced in the typical range of source-zone temperature. ScCl₂ and Sc₂Cl₆ can be produced in the selected temperature range of source zone but its amount should be limited. Furthermore, ScCl₂ can attach the chamber wall typically made of quartz by a chemical reaction between ScCl₂ and SiO₂. A reaction to produce ScCl₃ (chemical formula 3) shows the highest negative free energy, indicating that ScCl₃ is the major component of precursor. However, the Gibbs free energy of the reaction between ScCl₃ and NH₃ to produce ScN is positive; hence, the reaction is not thermodynamically possible in typical deposition temperatures. Therefore, HVPE cannot be employed for the deposition of transition-metal-alloyed III-N films. Nevertheless, the prior process of HVPE growth of ScN uses dominant precursors of ScCl₂ and Sc₂Cl₂. As described earlier, the growth rate of the film must be limited by the small amount of Sc-chloride precursors. Moreover, the epitaxial growth of controlled ScₓAl₁₋ₓN thin film has not been demonstrated by HVPE.

Another current sputtering technique for deposition of ScAlN uses either an alloyed target sputtering method or dual-target method. Unlike HVPE, this physical vapor deposition technique does not rely on chemical reaction. However, this technique has limitations in the quality and uniformity of materials. In the case of the dual-target co-sputtering method, the uniformity of film in terms of composition and thickness is difficult to maintain, especially when the films are deposited for high volume production. In the case of the Sc—Al alloyed target sputtering method, the composition of the film can be maintained for a long time. However, the size of the target is limited for high-Sc content of alloyed targets. The sputtered ScAlN films have been considered for enhanced piezoelectric properties because of the high solubility of Sc. However, aforementioned limitations in scalability and uniformity pose a serious challenge in high volume manufacturing. Furthermore, sputtered thin films typically contain higher density of crystalline defects than films grown by chemical vapor deposition (CVD) techniques, such as HVPE and MOCVD.

No current method that uses MBE for the deposition of the transition-metal-alloyed III-N are known. Methods involving epitaxial growth of MBE is known; however, all of them are related to traditional III-V compound semiconductors such as GaAs. Although an MBE growth method could improve the quality of grown thin film as compared to the sputtering deposition, the very low growth rate of the MBE process and the necessity of an extremely low-pressure growth limit make it difficult to be employed in large-scale industrial production.

Using MOCVD for the deposition of the transition-metal-alloyed III-N is preferred over MBE. However, MOCVD also faces a critical challenge in the growth of Sc-alloyed III-N that is related to the precursor of Sc. The major impediment to the growth of Sc- and Y-containing III-N film is the low vapor pressure of metalorganic precursors. Such low vapor pressures of metalorganic Sc and Y precursors cannot provide high enough molar flow rate to produce Sc- and Y-alloyed III-N films by MOCVD. As a result, for example, only 5×10¹⁸ cm⁻³ Y atoms (corresponding to several-hundred ppm-level concentration) have been alloyed into a GaN film using MOCVD, which is far below the alloy concentrations needed to evaluate the properties. Therefore, very few attempts to grow III-N layers alloyed with ScN have been successful, except for one case which deposited epitaxial layers with Sc content up to 30%. In that case, however, the deposition must presumably have been carried out at extremely low rate to compensate for very low molar flow rate of transition-metal precursors, negating the benefit of better manufacturability of the MOCVD process. Accordingly, using MOCVD for the growth of transition-metal-alloyed III-N film has significant drawbacks because of the lack of proper transition metal precursors and its low vapor pressure. Moreover, MOCVD makes it difficult to control a great number of parameters, which must be controlled to achieve the necessary uniformity and reproducibility.

The phase equilibria between transition-metal nitride (ScN and YN) and III-N (BAlGaN) to form a ternary alloy system, such as ScAlN, YAlN, ScGaN, YGaN, etc., show a phase separation with the formation of cubic rock-salt structure ScN (or YN) in wurtzite III-N film with increasing alloy composition of transition-metal nitride, resulting in degradation and eventually disappearance of its piezoelectric properties. Therefore, accurate control of alloy composition as well as high crystalline quality is required while maintaining a high-throughput manufacturable process. In embodiments of this invention, the inventors disclose a new deposition and epitaxial growth technique for high-quality controlled transition-metal alloyed III-N thin film with high-throughput process. The inventors developed a concept, method, and apparatus of the deposition and confirmed the feasibility of this new concept via thermodynamic calculation using the relevant precursors and reactions.

### III. Principles Applied in Invention Disclosure: Novel Aspects and Unique Features

For use of transition-metal alloyed III-N thin film in aforementioned applications, a technique for the deposition must provide high-quality and uniform films on relatively large multiple wafers per growth run at reasonably high deposition rates using an easily scalable high-throughput process. In embodiments of the present disclosure, an epitaxial thin-film growth technique coined as “hybrid chemical and physical vapor deposition” (HybCPVD) or “hybrid vapor phase epitaxy” (HybVPE) is described. In this technique, transition-metal-alloyed III-N single-crystalline and textured thin films are epitaxially and non-epitaxially deposited on a suitable substrate (of, for example, silicon or a metal such as aluminum or titanium) by providing a mixture of various gases in a deposition/growth chamber. The precursors for the chemical reactions include vapor phase of elements of group IIIb transition metals (herein referred to as transition metals), such as Sc and Y, vapor phase of chlorides of group IIIa elements (herein referred to as group III), such as AlCl₃, GaCl, InCl₃, and BCl₃, and vapor phase of hydride of group V element (N), such as NH₃. This growth technique can provide high growth rate and high-quality epitaxial materials.

Transition-metal-nitrides are formed by the following chemical reactions:

2Sc(g)+2NH₃(g)=2ScN(alloy)+3H₂(g) (chemical formula 5)

2Y(g)+2NH₃(g)=2YN(alloy)+3H₂(g) (chemical formula 6)

Vapor-phase transition metal is formed by heating the elemental source (Sc and Y) at high temperatures. The vapor pressures of the transition metals exponentially increases with the temperature up to the boiling point. High vapor pressure of the transition metal can be achieved at relatively high temperatures, since their boiling temperatures are very high (i.e., 2,836° C. for Sc and 3,338° C. for Y). This feature allows high molar flow rates of transition metal precursors of this new technique, compared to stand-alone MOCVD or HVPE, when reaction methods are limited by growth/etch rate at a given temperature. Group-III-nitrides are formed by the following chemical reactions:

AlCl₃(g)+NH₃(g)=AlN(alloy)+3HCl(g) (chemical formula 7)

GaCl(g)+NH₃(g)=GaN(alloy)+HCl(g)+H₂(g) (chemical formula 8)

InCl₃(g)+NH₃(g)=InN(alloy)+3HCl(g) (chemical formula 9)

BCl₃(g)+NH₃(g)=BN(alloy)+3HCl(g) (chemical formula 10)

These reactions are similar to ones used in HVPE, which is the most economical VPE process with high deposition rates. Therefore, HVPE may be used as a part of the disclosed embodiments set forth herein.

Alloyed (transition-metal)-(group-III)-nitrides are formed by a combination of the above reactions. For example, ScₓAl₁₋ₓN is formed by the following reaction:

x′Sc(g)+(1−x′)AlCl₃(g)+y′NH₃(g)=ScₓAl₁₋ₓN(s)+y3/2H₂(g)+z3HCl(g) (chemical formula 11)

In this reaction, the adjustment of a target solid composition ratio of Sc (x_{Sc}) and Al (x_{Al}=1−x_{Sc}) in ScAlN thin film is achieved by changing relative input amounts of the Sc precursor (x′_{Sc_precursor}) and Al precursor (x′_{Al_precursor}=1−x′_{Sc_precursor}). y′ is dependent on input V/III ratio of precursors, that is, (y′/(x′+1−x′). In addition to the precursors, carrier gases are mixed to transport the vapor-phase precursors. The carrier gases are inert gas (IG, N₂, or Ar) and/or hydrogen (H₂).

### IV. Design and Processes: Methods Differentiating from Previous Deposition Technologies

Unlike the other CVD techniques where a single type of precursor is used for each group, this HybCPVD (or HybVPE) technique employs three different types of precursors. A group-III precursor (source gas of chloride vapor of B, Al, Ga, and In), a transition-metal precursor (source gas of elemental vapor of Sc and Y), a nitrogen precursor (source gas of N), and a carrier gas are mixed to deposit transition-metal-alloyed III-N thin films.

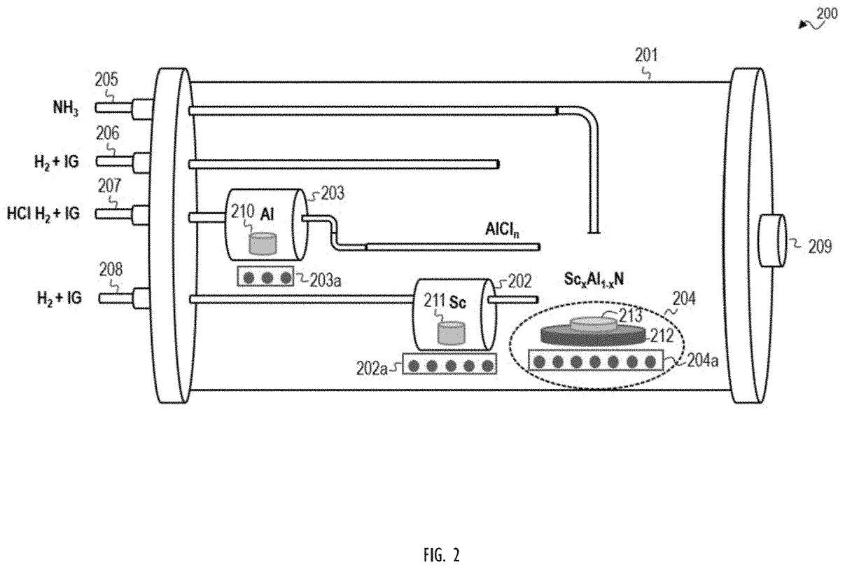

FIG. 2 is a diagram of a chamber 200 of the HybCPVD or HybVPE system for the deposition of transition-metal-alloyed III-N thin films according to exemplary embodiments.

In the embodiment of FIG. 2, the chamber 200 includes a chamber wall 201, a transition-metal precursor source zone 202 for storing a transition metal 211 (e.g., Sc or Y), a group-III precursor source zone 203 for storing a group III element 210 (e.g., B, Al, Ga, and In), a growth zone 204, a nitrogen precursor inlet tube 205, a transition-metal precursor inlet tube 207, a group-III precursor inlet tube 208, an additional carrier gases inlet tube 206, and an exhaust tube 209. The chamber wall 201 and inlet/exhaust tubes 205, 206, 207, 208, and 209 may be made of stainless steel, quartz, alumina, pyrolytic boron nitride, graphite, silicon-carbide-coated graphite, etc. or a combination of them. The system is configured with separate inputs for different precursors with different forms: chloride vapor of B, Al, Ga, or In (group-III precursors); vapor of elemental Sc or Y (a transition-metal precursor); and NH₃ gas (N precursor) to deposit various compositions of ternary alloy (transition-metal)ₓ-(group-III)₁₋ₓ-nitride, such as ScₓAl₁₋ₓN. Each part of the process and apparatus is described as follows:

### Supply of Group-III Precursor (e.g., Source Gas of Chloride Vapor of B, Al, Ga, and In).

The group-III element 211 (e.g., B, Al, Ga, or In) is stored in the group-III precursor source zone 203, for example in a container that can be made of quartz, alumina, pyrolytic boron nitride, graphite, silicon-carbide-coated graphite, etc. HCl gas along with carrier gas(es) are introduced into the group-III precursor source zone 203 through the group-III precursor inlet tube 207. The HCl reacts with the group-III element 211 to produce a vapor-phase chloride of the group III precursor (e.g., AlClₙ). The group III precursor is transported to the growth zone 204 by the carrier gases. The amount of group-III precursor can be controlled by changing the amount/flow rate of HCl and the temperature of group-III precursor source zone 203. The amount of HCl and carrier gases are separately controlled by mass flow controllers (MFCs). The temperature of the group-III element 211 may be controlled and maintained by a heater 203a for the formation of the appropriate form of a chloride.

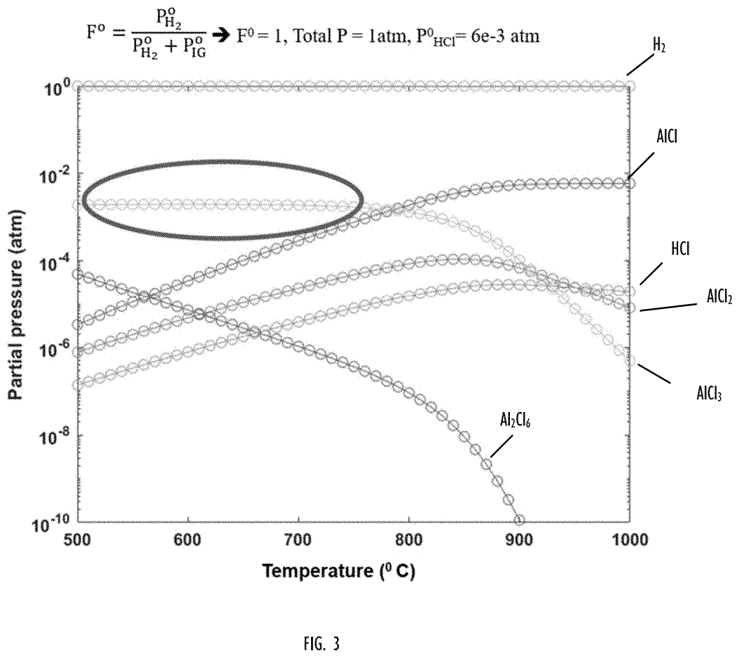

In the case of a reaction chamber and liner made of quartz (SiO₂), AlCl₃ is a preferred group III precursor over AlCl and AlCl₂, which may cause damage to the chamber. For example, AlCl₃ can be dominantly formed over AlCl, AlCl₂, and Al₂Cl₆ in the temperature range below 700° C., as shown in FIG. 3 considering the thermodynamics of various reactions between HCl and Al. A reaction for the formation AlCl₃ is:

2Al+6HCl=2AlCl₃+3H₂ (chemical formula 12)

### Supply of Transition-Metal Precursor (e.g., Source Gas of Elemental Vapor of Transition Metal).

The transition metal 211 (e.g., Sc or Y in a solid or liquid phase) is stored in the transition-metal precursor source zone 202, for example in a container that can be made of pyrolytic boron nitride, graphite, silicon-carbide-coated graphite, quartz, alumina, etc. Carrier gas(es) with a flow rate controlled by an MFC are introduced to the transition-metal precursor source zone 202 through the transition-metal precursor inlet tube 208 and transport the vapor of the transition metal 211 to the growth zone 204. The amount of transition metal precursor can be controlled by changing the temperature of transition metal 211 via a heater 202a (thereby changing the equilibrium vapor pressure of the transition metal) and/or by controlling the flow rate of the carrier gas(es) over the transition metal 211 (e.g., using the MFC).

Supply of a nitrogen precursor Ammonia (NH₃), as a precursor of N, is introduced through the nitrogen precursor inlet tube 205. The amount of NH₃ may be controlled by an MFC. The ammonia along with a mixture of the hydrogen gas (H₂) and the (inert) carrier gas (IG) is guided to the growth zone 204. Different amounts of carrier gas, including hydrogen, may be used.

Additional carrier gases, such as IG and H₂, may be introduced through the additional carrier gas inlet tube 206. The amount of each gas may be controlled by an MFC. Different amounts and ratios of carrier gases between IG and H₂ may be considered for the reactions in the growth zone 204.

The growth zone 204 may include a susceptor 212 and a heater 204a. In the growth zone 204, all the precursors (including vapor of group-III-chloride, vapor of transition-metal element, and NH₃) and carrier gases may be mixed. A substrate 213, on which transition-metal-alloyed III-N thin film is grown, may be placed on a susceptor 212. The heater 204a may be provided to maintain the substrate 213 at a proper temperature for the chemical reaction followed by deposition.

### V. Additional Observations

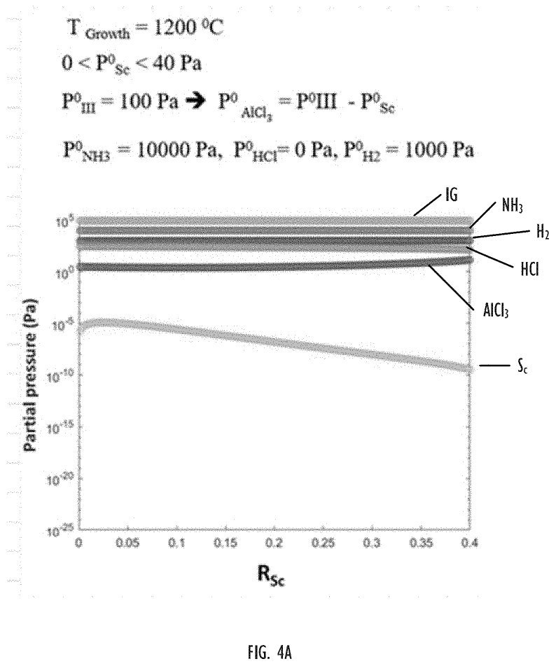

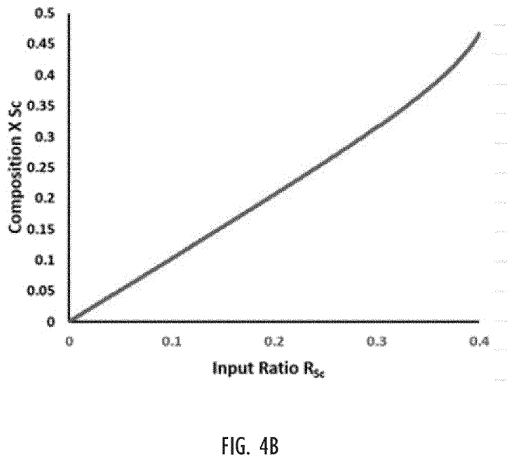

The disclosed embodiments show the feasibility of deposition and control on the ScₓAl₁₋ₓN compositions at various temperatures, input V/III ratios, and carrier gas partial pressures. Thermodynamics is used to investigate the feasibility of the formation of transition-metal-alloyed films with varied compositions, x, depending on various parameters of the deposition in the embodiment. Thermodynamic calculation shows the controllability of x at various temperatures, input V/III ratios, and input carrier gas ratios in different parts of source zones and growth zone. FIG. 4 shows a representative result of the calculation in the case of ScₓAl₁₋ₓN at a condition: growth temperature, T_{growth}=1200° C., NH₃ input partial pressure, P°_{NH3}=10000 Pa, input hydrogen carrier gas partial pressure, P°_{H2}=1000 Pa, and V/III ratio, P°_{NH3}/(P°_{Sc}+P°_{AlCl3})=100. Input partial pressures of Sc precursor (Sc), P°_{Sc}, and Al precursor (AlCl₃), P°_{AlCl3}, are varied while maintaining the same V/III ratio, hence the same total input pressures of Sc and Al precursors, P°_{Sc}+P°_{AlCl3}=100 Pa. The ratio of input III precursors, R_{Sc}, is defined as

$${R}_{S c} = \frac{{P}_{S c}^{o}}{{P}_{{AlCl}_{3}}^{o} + {P}_{S c}^{o}} \qquad ( chemical formula 13 )$$

Referring to FIG. 4A, the plot shows the changes in equilibrium partial pressures, P_{AlCl3}, P_{NH3}, P_{Sc}, P_{H2}, P_{HCl}, and P_{IG}, of reactants and products of the chemical reaction at varied R_{Sc} in the growth zone. The differences between input partial pressure and equilibrium partial pressure of transition metal (P°_{Sc}−P_{Sc}) and group III element (P°_{AlCl3}−P_{AlCl3}) is related to the driving force of the deposition and results in the relative ratio of Sc and Al in the deposited film. FIG. 4B shows the relationship between the R_{Sc} and x. The equilibrium partial pressures and relationship show that the deposition of the alloyed ScAlN occurs in proper conditions, and their composition is controllable by adjusting the input ratio of transition metal and group-III precursors using the method described in embodiments of this invention. Therefore, the HybCPVD (or HybVPE) method can provide an effective route to deposit transition-metal-alloyed III-N thin film with high quality, better manufacturability, and with better controllability as compare to other growth methods.

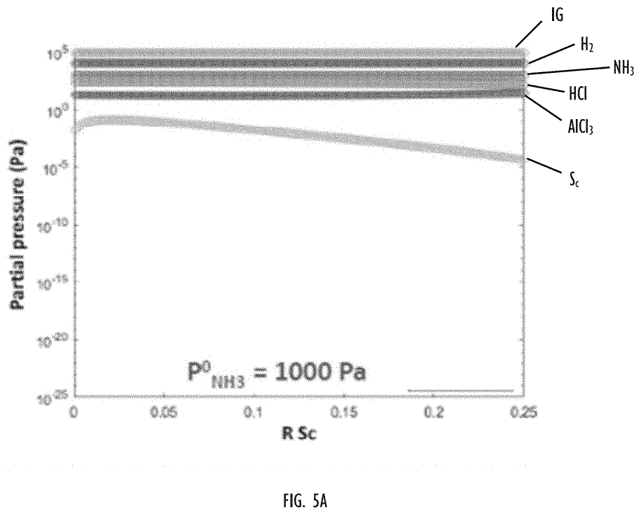

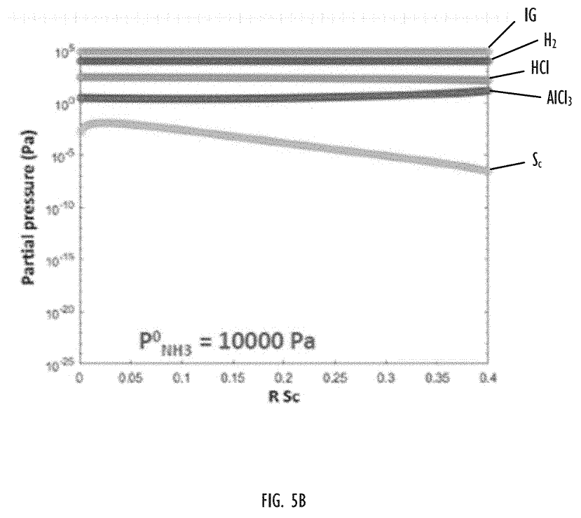

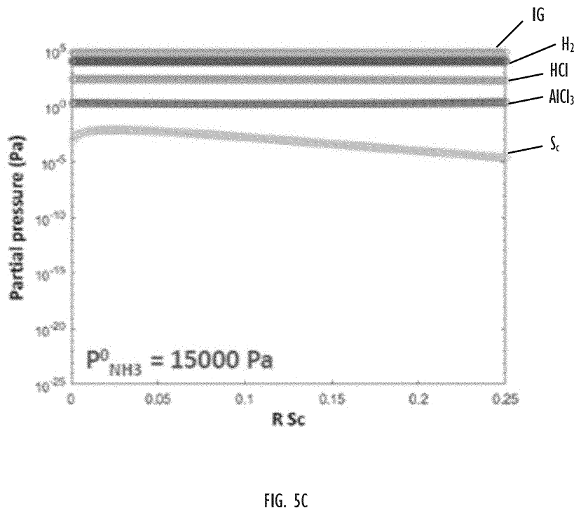

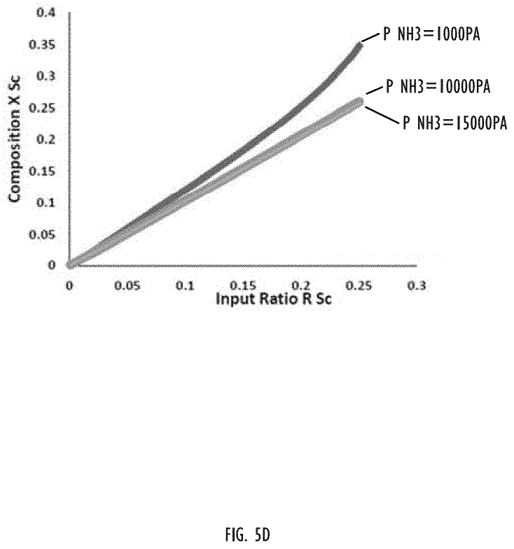

FIGS. 5A-D show other examples of alloyed ScAlN thin film using modified deposition parameters, including, equilibrium partial pressures (FIGS. 5A-5C) and R_{Sc} vs x (FIG. 5D). The calculation indicates that increasing the NH₃ along with increasing the input V/III ratio results in a decrease in Sc composition in the film due to decreasing the driving force of ScN deposition (P°_{Sc}−P_{Sc}). According to the thermodynamic calculations, the driving force for the deposition (P°_{III}−P_{III}) of the growth zone is high enough to deposit ScAlN film with Sc content of up to 30% which is critical for the improvement of piezoelectric properties of AlN alloy by the HybCPVD method.

### VI. Expected Outcomes: Advantages and Usability

The present disclosure describes a technique, HybCPVD (or HybVPE), for the deposition and epitaxial growth of transition-metal-alloyed III-N thin films by combining a solid-source precursor, a chloride precursor, and ammonia to address the limitations in the currently developed techniques. Thermodynamics study shows that the chemical reactions using the suggested precursor occur and provides critical information for the experiment conditions to achieve a controlled composition of ScₓAl₁₋ₓN in the range of Sc≤0.3 by HybCPVD. This high-throughput manufacturable technique for deposition of the high-quality piezoelectric and ferroelectric film will bring significant impacts in extended applications of wireless communication, energy harvesting, sensing, and ferroelectric semiconductors.

### VII. Examples of Embodiments

The present disclosure includes an original design concept and method of processes for a new deposition and epitaxial growth technique coined by hybrid chemical and physical vapor deposition (HybCPVD) or hybrid vapor phase epitaxy (HybVPE). The following non-limiting exemplary features are hereby disclosed:

The deposition and epitaxial growth of alloyed nitride film consisting of transition metal (including scandium, yttrium, etc. of group IIIb or group 3) and group III element (including boron, aluminum, gallium, and indium of group IIIa or group 13) by using a combination of different forms of precursors.

The precursor of transition metal is the vapor phase of the element using its equilibrium vapor pressure over the solid source at high temperatures below its boiling temperature.

The combination of elemental, metalorganic, chloride, and hydride vapor precursors preformed or formed in situ independently or in combination of two or three different precursors for single or multiple elements.

The precursor of group-III element is vapor-phase chloride form of the element produced by the reaction between the element and HCl at a controlled temperature.

The precursor of N element is ammonia (NH₃).

The precursors are premixed or mixed in the growth zone including substrate, susceptor, and heaters for the deposition and epitaxial growth of transition-metal-alloyed III-N thin film on a substrate.

The combination of three methods to make the alloys of semiconductors, semimetals, metal, semiconductors, and insulators.

The apparatus used to combine these methods.

The materials produced using the apparatus.

The combination of these methods with a list of materials.

The combination of these methods simultaneously sequentially or cyclically.

The combinations of these methods either etch or grow.

The combination of these methods to change the alloy composition.

The combination of these methods with one or more gas precursors.

The combination of these methods with one or more solid precursors.

The combination of these methods to grow crystalline or amorphous materials.

The combination of these methods to grow materials of thickness 1 nm to 1 mm.

The combination of these methods to produce homo and heteroepitaxial films.

The combinations of methods in which the sources temperatures are 200° C. to 2500° C.

The combination of methods in which the substrate temperatures can vary 500° C. to 2000° C.

The combination of methods in which the precursor concentration can vary 0.2 μmol/min to 45000 μmole/min.

The combination of methods in which the pressure of growth can vary from 10 Torr to 760 Torr.

The combination of methods to grow continually graded or step graded alloys.

The combination of methods to grow material on flat non-flat substrates/objects.

The flow of precursors perpendicular or parallel or at any angle of inclination 0 to 90 degrees to substrate surface.

The combination of methods to grow device structures without breaking vacuum or exposing to atmosphere.

The combination of these methods to grow materials with high piezoelectric and ferroelectric properties.

### VIII. Additional Examples of Embodiments

One or more embodiments of the present disclosure are directed to a semiconductor structure including a substrate and a piezoelectric semiconductor film disposed above the substrate. The piezoelectric semiconductor film includes at least one characteristic selected from the group consisting of: a piezoelectric coefficient d₃₃ in a range greater than 25 pC/N; an electromechanical coupling factor kₜ² in a range greater than 10%, a crystalline quality in terms of full-width-at-half-maximum from (0002) X-ray diffraction rocking curves in a range of less than 2°, and combinations thereof.

In an embodiment, the piezoelectric semiconductor film includes the following characteristics: the piezoelectric coefficient d₃₃ in a range greater than 25 pC/N and the crystalline quality in terms of full-width-at-half-maximum from (0002) X-ray diffraction rocking curves in a range of less than 2°.

In an embodiment, the piezoelectric semiconductor film includes a thickness uniformity of less than 10% with respect to the underlying substrate having a diameter of 2 inches or greater.

In an embodiment, the piezoelectric semiconductor film includes a transition-metal-alloyed III-N piezoelectric semiconductor film. In one embodiment, the transition-metal-alloyed III-N piezoelectric semiconductor film includes an alloy from a combination of a group IIIb-nitride and a group IIIa-nitride. In another embodiment, the alloy includes at least one alloy composition selected from the group consisting of ScₓAl₁₋ₓN, ScₓB₁₋ₓN, ScₓGa₁₋ₓN, ScₓIn₁₋ₓN, YₓAl₁₋ₓN, YₓB₁₋ₓN, YₓGa₁₋ₓN, YₓIn₁₋ₓN, and combinations thereof.

In an embodiment, the semiconductor structure is included as part of at least one device selected from the group consisting of a wireless communication device, a sensor, a mechanical energy harvesting device, a ferroelectric semiconductor, and combinations thereof.

In an embodiment, the semiconductor structure is prepared by a process that includes providing the substrate, and forming the piezoelectric semiconductor film on the substrate via physical vapor deposition or vapor phase epitaxy, using the following precursors: a vapor phase chloride form of a group-III element, a vapor phase of a pure transition metal, and ammonia.

Embodiments are also directed to a method of fabricating a semiconductor structure. The method includes providing a substrate, and forming a piezoelectric semiconductor film on the substrate via physical vapor deposition or vapor phase epitaxy, using the following precursors: a vapor phase chloride form of a group-III element, a vapor phase of a pure transition metal, and ammonia.

In an embodiment, the piezoelectric semiconductor film includes at least one characteristic selected from the group consisting of: a piezoelectric coefficient d₃₃ in a range greater than 25 pC/N, an electromechanical coupling factor kₜ² in a range greater than 10%, a crystalline quality in terms of full-width-at-half-maximum from (0002) X-ray diffraction rocking curves in a range less than 2°, and combinations thereof.

In an embodiment, the piezoelectric semiconductor film includes the following characteristics: the piezoelectric coefficient d₃₃ in a range greater than 25 pC/N and the crystalline quality in terms of full-width-at-half-maximum from (0002) X-ray diffraction rocking curves in a range of less than 2°.

In an embodiment, the piezoelectric semiconductor film includes a thickness uniformity of less than 10% with respect to the underlying substrate having a diameter of 2 inches or greater.

In an embodiment, wherein the piezoelectric semiconductor film includes a transition-metal-alloyed III-N piezoelectric semiconductor film. In one embodiment, the transition-metal-alloyed III-N piezoelectric semiconductor film includes an alloy from a combination of a group IIIb-nitride and a group IIIa-nitride. In another embodiment, the alloy includes at least one alloy composition selected from the group consisting of ScₓAl₁₋ₓN, ScₓB₁₋ₓN, ScₓGa₁₋ₓN, ScₓIn₁₋ₓN, YₓAl₁₋ₓN, YₓB₁₋ₓN, YₓGa₁₋ₓN, YₓIn₁₋ₓN, and combinations thereof.

In an embodiment, the semiconductor structure fabricated by the method is included as part of at least one device selected from the group consisting of a wireless communication device, a sensor, a mechanical energy harvesting device, a ferroelectric semiconductor, and combinations thereof.

The method steps in any of the embodiments described herein are not restricted to being performed in any particular order. Also, structures mentioned in any of the method embodiments may utilize structures mentioned in any of the device/system embodiments. Such structures may be described in detail with respect to the device/system embodiments only but are applicable to any of the method embodiments.

Features in any of the embodiments described above may be employed in combination with features in other embodiments described above; such combinations are within the spirit and scope of the present invention.

The contemplated modifications and variations specifically mentioned above are within the spirit and scope of the present invention.

It is understood that the above description is intended to be illustrative and not restrictive. The material has been presented to enable any person skilled in the art to make and use the concepts described herein and is provided in the context of particular embodiments, variations of which will be readily apparent to those skilled in the art (e.g., some of the disclosed embodiments may be used in combination with each other). Many other embodiments will be apparent to those of skill in the art upon reviewing the above description. The scope of the embodiments herein, therefore, should be determined with reference to the appended claims, along with the full scope of equivalents to which such claims are entitled. In the appended claims, the terms “including” and “in which” are used as the plain English equivalents of the respective terms “comprising” and “wherein.”

What is claimed is:

1. A process for fabricating a semiconductor structure, the process comprising:
providing a substrate; and
forming a piezoelectric semiconductor film on the substrate using a vapor phase chloride form of a group-III element, a vapor phase of a pure transition metal, and ammonia.

2. The process of claim 1, wherein forming the piezoelectric semiconductor film includes at least of physical vapor deposition and vapor phase epitaxy.

3. The method of claim 1, wherein the piezoelectric semiconductor film comprises one or more characteristics selected from the group comprising: a piezoelectric coefficient d₃₃ in a range greater than 25 pC/N, an electromechanical coupling factor kₜ² in a range greater than 10%, and a crystalline quality in terms of full-width-at-half-maximum from (0002) X-ray diffraction rocking curves in a range of less than 2°.

4. The method of claim 1, wherein the piezoelectric semiconductor film comprises a piezoelectric coefficient d₃₃ in a range greater than 25 pC/N.

5. The method of claim 1, wherein the piezoelectric semiconductor film comprises a crystalline quality in terms of full-width-at-half-maximum from (0002) X-ray diffraction rocking curves in a range of less than 2°.

6. The method of claim 1, wherein the substrate has a diameter of 2 inches or greater.

7. The method of claim 1, wherein the piezoelectric semiconductor film comprises a thickness uniformity of less than 10% of the substrate's diameter.

8. The method of claim 1, wherein the piezoelectric semiconductor film comprises a transition-metal-alloyed III-N piezoelectric semiconductor film.

9. The method of claim 8, wherein the transition-metal-alloyed III-N piezoelectric semiconductor film comprises an alloy from a combination of a group IIIb-nitride and a group IIIa-nitride.

10. The method of claim 9, wherein the alloy comprises at least one alloy composition selected from the group consisting of ScₓAl₁₋ₓN, ScₓB₁₋ₓN, ScₓGa₁₋ₓN, ScₓIn₁₋ₓN, YₓAl₁₋ₓN, YₓB₁₋ₓN, YₓGa₁₋ₓN, and YₓIn₁₋ₓN.

11. An apparatus for fabricating a substrate, the apparatus comprising:
a first source zone;
a second source zone;
a growth zone;
a plurality of heating elements, wherein each of the heating elements provides heat to one of the first source zone, the second source zone, or the growth zone; and
a plurality of tubing elements, wherein one or more of the tubing elements connect the first zone and the second zone to the growth zone.

12. The apparatus of claim 11, wherein the apparatus includes a hybrid chemical vapor deposition chamber.

13. The apparatus of claim 11, wherein the apparatus includes a hybrid vapor phase epitaxy chamber.

14. The apparatus of claim 11, the apparatus further comprising:
a plurality of gas inlets connected to the first and second source zones via one or more of the tubing elements.

15. The apparatus of claim 11, wherein the substrate is a semiconductor.

16. A method, comprising:
supplying a first source gas to a first zone;
supplying a second source gas to a second zone;
supplying a nitrogen precursor to a growth zone;
transporting the source gas of chloride vapor from the first zone to the growth zone;
transporting the source gas of elemental vapor of transition metal from the second zone to the growth zone; and
mixing the first source gas, the second source gas, and the third source gas to create a substrate.

17. The method of claim 16, wherein the first source gas is chloride vapor.

18. The method of claim 16, wherein the second source gas is an elemental vapor of a transition metal.

19. The method of claim 16, wherein the third source gas is a nitrogen precursor.

20. The method of claim 16, further comprising:
maintaining said first source gas in the first zone using a first heating element; and
maintaining said second source gas in the second zone using a second heating element.
